(19) United States
(12) Patent Application Publication
(10) Pub. No.: US 2008/0105908 A1
(43) Pub. Date: May 8, 2008

(54) Image sensor and method of forming the same

(75) Inventor: Jun-taek Lee, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/982,925

(22) Filed: Nov. 6, 2007

(30) Foreign Application Priority Data
Nov. 6, 2006 (KR) 10-2006-0109130

(51) Int. Cl. H01L 31/0232; H01L 31/18

(52) U.S. Cl. 257/290; 257/435; 438/69; 257/E31.127; 257/E21.04

(57) ABSTRACT

An image sensor and a method of forming the same includes a semiconductor substrate including a light receiving area and an optical black area defined by a boundary between them; photodiodes in at least one of the light receiving area and the optical black area of the semiconductor substrate; an interlayer dielectric provided on the semiconductor substrate; an upper light shielding pattern on the interlayer dielectric to cover the optical black area; and a light shielding pattern provided in the interlayer dielectric proximal to the boundary between the optical black area and the light receiving area.

### CROSS-REFERENCE TO RELATED APPLICATIONS

This U.S. non-provisional patent application claims priority under 35 U.S.C. § 119 of Korean Patent Application No. 10-2006-0109130, filed on Nov. 6, 2006, the contents of which are hereby incorporated by reference in their entirety.

### BACKGROUND OF THE INVENTION

The present invention disclosed herein relates to an image sensor and a method of forming the same, and more particularly, to an image sensor having an optical black area and a method of forming the same.

An image sensor converts an optical image into an electrical signal. The image sensor may be largely classified as either a charge coupled device (CCD) image sensor-or a complementary metal-oxide-semiconductor (CMOS) image sensor. The image sensor includes photodiodes that receive light and transistors that control image signals input from the photodiodes. Since the image sensor is a device that converts an optical signal into an electrical signal, electrons generated due to heat or the like should be excluded from an output signal. Thus, an optical black area of the image sensor,.where photoelectric conversion does not occur, is required in order to exclude the electrons that may be generated due to heat or the like. Devices, for example, transistors, in the optical black area operate such that they are shielded from light. Charges generated in the optical black area are different from charges generated by light. Thus, an amount of the charges that are generated in the optical black area can serve as a reference signal.

Oblique light may be incident to a light receiving area and the optical black area. Oblique light incident to the optical black area is usually shielded by a light shielding layer of the optical black area. However, oblique light incident to the light receiving area is reflected from a metal interconnection disposed in the light receiving area and the optical black area, and can extend to the optical black area. This may cause optical cross-talk where charges are generated in the optical black area serving as the reference signal, and can affect the reference signal, resulting in decrease in image quality of the image sensor.

### SUMMARY OF THE INVENTION

Embodiments of the present invention are directed to an image sensor with improved image quality and a method of forming the same.

In one aspect, an image sensor comprises a semiconductor substrate including a light receiving area and an optical black area defined by a boundary between them, photodiodes in at least one of the light receiving area and the optical black area of the semiconductor substrate, an interlayer dielectric on the semiconductor substrate, an upper light shielding pattern on the interlayer dielectric to cover the optical black area, and a light shielding pattern in the interlayer dielectric proximal to the boundary between the optical black area and the light receiving area.

In an embodiment, the light shielding pattern is interposed between the upper light shielding pattern and a photodiode of the photodiodes in the optical black area.

In an embodiment, the light shielding pattern connects the photodiode in the optical black area to the upper light shielding pattern.

In an embodiment, a bottom surface of the light shielding pattern is lower than a top surface of the semiconductor substrate.

In an embodiment, the light shielding pattern comprises the same material as the upper light shielding pattern.

In an embodiment, the image sensor further comprises at least one transistor adjacent the photodiodes and a metal interconnection disposed on the interlayer dielectric to cover the at least one transistor.

In an embodiment, the light shielding pattern comprises the same material as the metal interconnections.

In an embodiment, the optical black area comprises a first optical black area adjacent the light receiving area and a second optical black area adjacent the first optical black area and separated from the light receiving area, the light shielding pattern in the first optical black area.

In an embodiment, the light receiving area is surrounded by the optical black area.

In an embodiment, the optical black area is disposed at one side of the light receiving area.

In another aspect, method of forming an image sensor comprises preparing a semiconductor substrate including a light receiving area and an optical black area defined by a boundary between them, forming photodiodes in at least one of the light receiving area and the optical black area of the semiconductor substrate, forming an interlayer dielectric on the semiconductor substrate, forming a light shielding pattern in the interlayer dielectric proximal to the boundary between the light receiving area and the optical black area, and forming an upper light shielding pattern on the interlayer dielectric in the optical black area.

In an embodiment, the light shielding pattern is formed between the upper light shielding pattern and the photodiode in the optical black area.

In an embodiment, the forming of the light shielding pattern comprises forming a contact hole in the interlayer dielectric such that the photodiode in the optical black area is exposed and forming a metal layer to fill the contact hole.

In an embodiment, at least one transistor adjacent the photodiodes is formed over the semiconductor substrate and a metal interconnection is formed on the interlayer dielectric to cover the at least one transistor.

In an embodiment, forming the interlayer dielectric comprises forming a first interlayer dielectric, forming a second interlayer dielectric on the first interlayer dielectric, and forming a third interlayer dielectric on the second interlayer dielectric, wherein forming the light shielding pattern comprises forming a first light shielding pattern that is connected to the photodiode of the optical black area in the first interlayer dielectric, forming a second light shielding pattern that is connected to the first light shielding pattern in the second interlayer dielectric, and forming a third light shielding pattern that is connected to the second light shielding pattern in the third interlayer dielectric.

In an embodiment, forming the metal interconnection comprises forming a first metal interconnection on the first interlayer dielectric and forming a second metal interconnection on the second interlayer dielectric to cover the first metal interconnection, wherein the first light shielding pattern and the first metal interconnection are formed at the same time, wherein the second light shielding pattern and the second metal interconnection are formed at the same time, and wherein the third light shielding pattern and the upper light shielding pattern are formed at the same time.

In an embodiment, forming the interlayer dielectric comprises forming a first interlayer dielectric, forming a second interlayer dielectric on the first interlayer dielectric, and forming a third interlayer dielectric on the second interlayer dielectric, wherein forming the light shielding pattern comprises forming a second light shielding pattern in the second interlayer dielectric and forming a third light shielding pattern that is connected to the second light shielding pattern in the third interlayer dielectric.

In an embodiment, forming the metal interconnection comprises forming a first metal interconnection on the first interlayer dielectric and forming a second metal interconnection on the second interlayer dielectric to cover the first metal interconnection, wherein the second light shielding pattern and the second metal interconnection are formed at the same time, and wherein the third light shielding pattern and the upper light shielding pattern are formed at the same time.

In an embodiment, the optical black area comprises a first optical black area adjacent the light receiving area and a second optical black area adjacent the first optical black area and separated from the light receiving area, wherein the light shielding pattern is formed in the first optical black area.

In an embodiment, the light receiving area is surrounded by the optical black area.

In an embodiment, the optical black area is formed at least at one side of the light receiving area.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. The embodiments depicted herein are provided by way of example, not by way of limitation, wherein like reference numerals refer to the same or similar elements. The drawings are not necessarily to scale, emphasis instead being placed upon illustrating aspects of the invention. In the drawings:

FIG. 1 is a sectional view of an image sensor according to an embodiment of the present invention;

FIG. 2 is a sectional view of an image sensor according to another embodiment of the present invention;

FIG. 3 is a sectional view of an image sensor according to another embodiment of the present invention;

FIG. 4 is a sectional view of an image sensor according to a modified example of the present invention;

FIGS. 5A through 5C are sectional views illustrating a method of forming an image sensor according to an embodiment of the present invention;

FIGS. 6A through 6C are sectional views illustrating a method of forming an image sensor according to another embodiment of the present invention;

FIGS. 7A through 7C are sectional views illustrating a method of forming an image sensor according to yet another embodiment of the present invention; and

FIGS. 8 through 10 are plan views illustrating a pixel array of an image sensor according to embodiments of the present invention.

### DETAILED DESCRIPTION OF EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer is referred to as being ‘on’ another layer or substrate, it can be directly on the other layer or substrate, or intervening layers may also be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

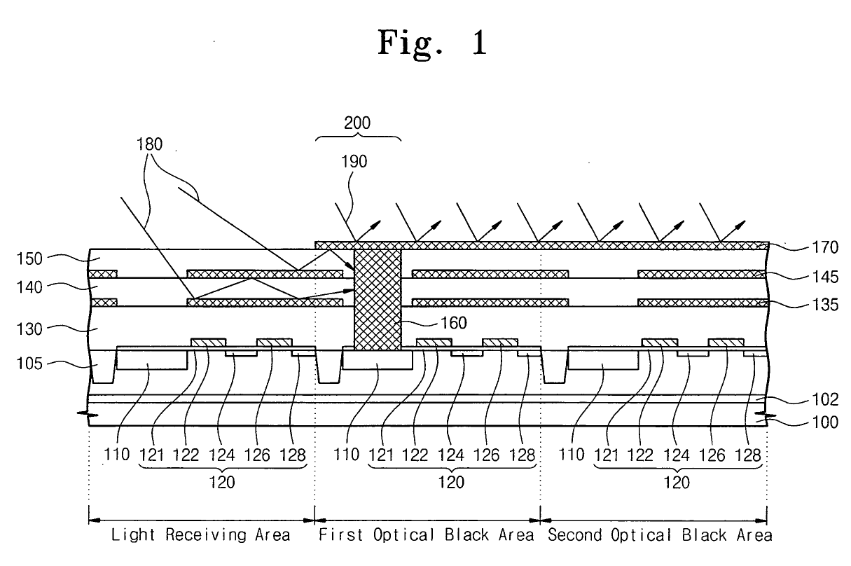

FIG. 1 is a sectional view of an image sensor according to an embodiment of the present invention.

Referring to FIG. 1, a semiconductor substrate 100 includes a light receiving area and an optical black area. The optical black area may include a first optical black area adjacent the light receiving area and a second optical black area adjacent the first optical black area. The second optical black area may include one or more unit pixels. The semiconductor substrate 100 may include P-type impurities. A P-well 102 may be provided for insulating devices in the semiconductor substrate 100. A device isolation layer 105 is provided in the semiconductor substrate 100 to define an active region of each unit pixel. Photodiodes 110 are provided in the light receiving area, and the first and second optical black areas of the semiconductor substrate 100, respectively. The photodiodes 110 are photoelectric conversion components that generate electron-hole pairs using incident light. Transistors 120 are provided on the semiconductor substrate 100 such that they are disposed adjacent the photodiodes 110. Each of the transistors 120 may include a gate insulating layer 121, a transfer gate 122, a floating diffusion region 124, a reset gate 126, and a reset drain region 128.

A first interlayer dielectric 130 is provided to cover the photodiodes 110 and the transistors 120. A first metal interconnection 135 is provided on the first interlayer dielectric 130 to cover the transistors 120. A second interlayer dielectric 140 is provided to cover the first interlayer dielectric 130 and the first metal interconnection 135. A second metal interconnection 145 is provided on the second interlayer dielectric 140 to cover the first metal interconnection 135. The first and second metal interconnections 135 and 145 may be electrically connected to the transistors 120. The first and second metal interconnections 135 and 145 may include, for example, aluminum (Al), copper (Cu), tungsten (W), titanium (Ti), or titanium nitride (TiN). A third interlayer dielectric 150 is provided to cover the second metal interconnection 145 and the second interlayer dielectric 140. The first through third interlayer dielectrics 130, 140 and 150 may include a silicon oxide layer with good light transmittance. An upper light shielding pattern 170 is provided on the third interlayer dielectric 150 to cover the first and second optical black areas. The upper light shielding pattern 170 may shield oblique light 190 incident to the optical black area. The upper light shielding pattern 170 may include the same material as the first and second metal interconnections 135 and 145.

The image sensor further comprises a boundary 200 between the light receiving area and the optical black area. A light shielding pattern 160 is provided in the boundary 200 between the light receiving area and the optical black area. The light shielding pattern 160 may be provided in the first through third interlayer dielectrics 130, 140 and 150. The light shielding pattern 160 may be interposed between the upper light shielding pattern 170 and the photodiode 110 in the first optical black area. The light shielding pattern 160 may connect the photodiode 110 in the first optical black area with the upper light shielding pattern 170. The light shielding pattern 160 may include the same material as the first and second metal interconnections 135 and 145, for example, aluminum (Al), copper (Cu), tungsten (W), titanium (Ti), or titanium nitride (TiN). Also, the light shielding pattern 160 may include the same material as the upper light shielding pattern 170. Since the light shielding pattern 160 is provided in the boundary 200 between the light receiving area and the optical black area, the light shielding pattern 160 can prevent oblique light 180 from being incident to the optical black area, even though the oblique light 180 is incident to the light receiving area. Therefore, optical cross-talk is prevented, and therefore, the image sensor can stably realize an image.

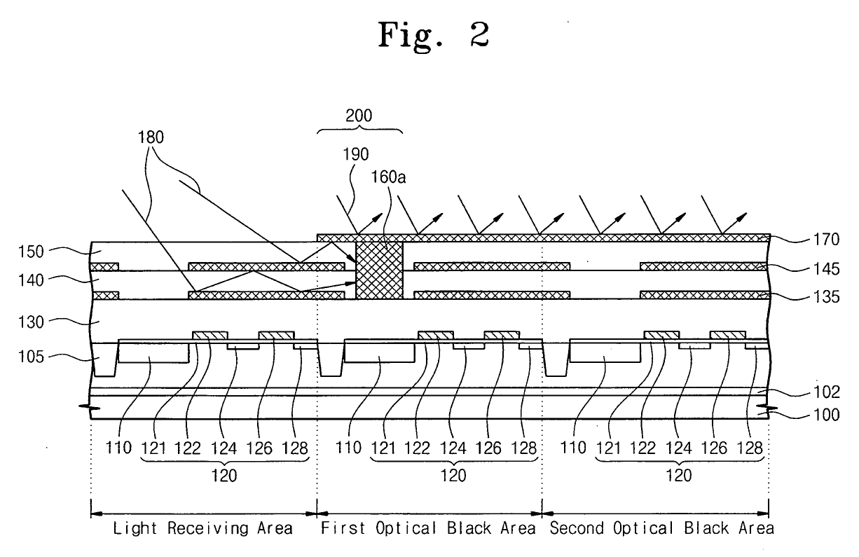

FIG. 2 is a sectional view of an image sensor according to another embodiment of the present invention. Referring to FIG. 2, as distinguished from the light shielding pattern 160 of FIG. 1, which is provided in first, second, and third interlayer dielectrics 130, 140 and 150, a light shielding pattern 160a shown in FIG. 2 is provided in the second and third interlayer dielectrics 140 and 150. The light shielding pattern 160a may be connected to the upper light shielding pattern 170. The light shielding pattern 160a may sufficiently reduce the amount of the oblique light 180 incident to the optical black area.

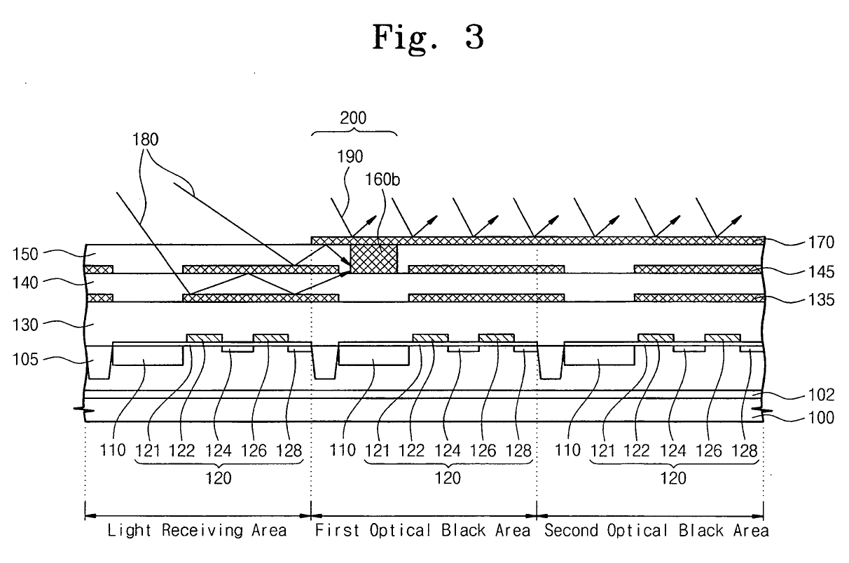

FIG. 3 is a sectional view of an image sensor according to another embodiment of the present invention. Referring to FIG. 3, as distinguished from the light shielding pattern 160a of FIG. 2, which is provided in second and third interlayer dielectrics 140 and 150, a light shielding pattern 160b shown in FIG. 2 is provided only in the third interlayer dielectric 150. The light shielding pattern 160b may be connected to the upper light shielding pattern 170. The light shielding pattern 160b may reduce the amount of the oblique light 180 incident to the optical black area.

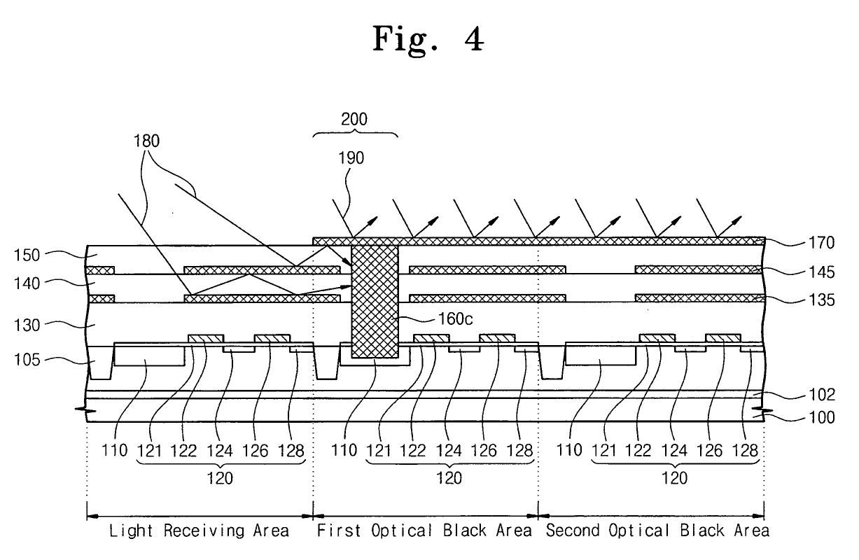

FIG. 4 is a sectional view illustrating an image sensor according to a modified example of the present invention. Referring to FIG. 4, as distinguished from the light shielding pattern 160 of FIG. 1, a light shielding pattern 160c shown in FIG. 4 may penetrate a portion of the photodiode 110 in the first optical black area. That is, a bottom surface of the light shielding pattern 160c may be lower than a top surface of the semiconductor substrate 100.

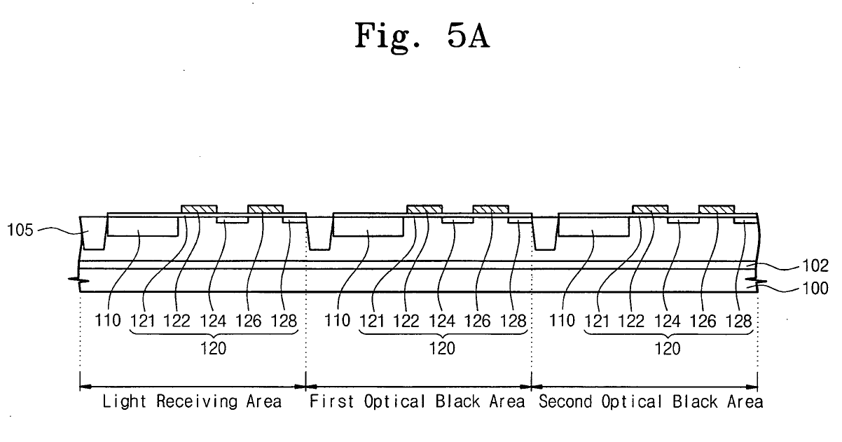

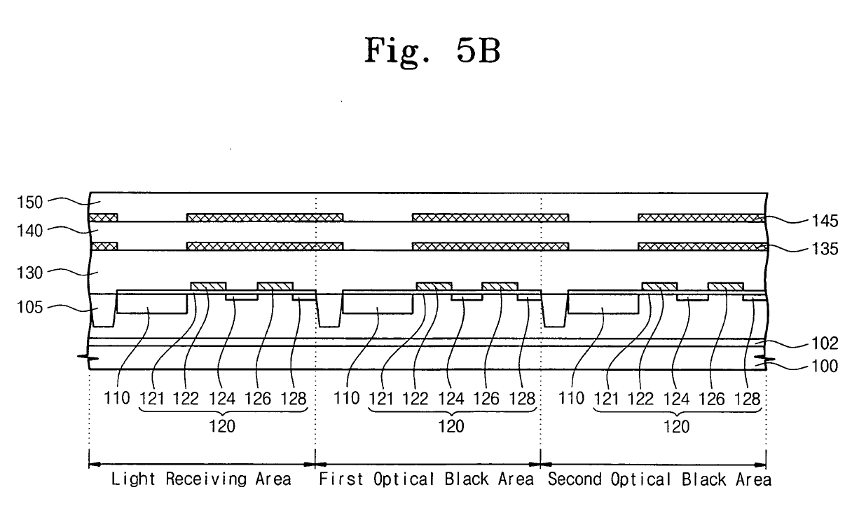

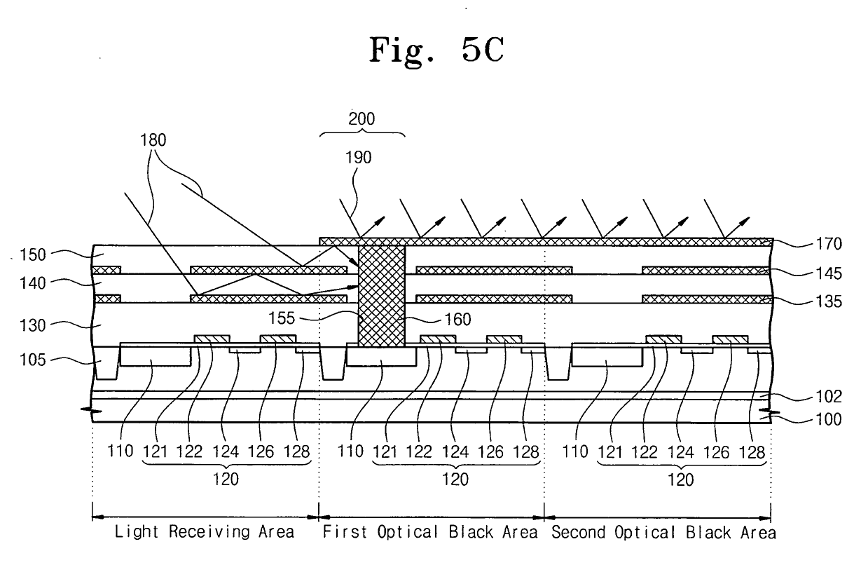

FIGS. 5A through 5C are sectional views illustrating a method of forming an image sensor according to an embodiment of the present invention.

Referring to FIG. 5A, a semiconductor substrate 100 includes a light receiving area, a first optical black area, and a second optical black area. A P-well 102 may be formed in the semiconductor substrate 100. A device isolation layer 105 is formed in the semiconductor substrate 100 to define an active region in each unit pixel. The device isolation layer 105 may be formed using a shallow trench isolation method. A gate insulating layer 121 is formed on the semiconductor substrate 100. The gate insulating layer 121 may be formed using a thermal oxidation process. A transfer gate 122 and a reset gate 126 are formed on the gate insulating layer 121. The transfer gate 122 and the reset gate 126 may include polysilicon formed by using a chemical vapor deposition (CVD) method. An ion implant process is performed on the semiconductor substrate 100 adjacent the transfer gate 122 to form photodiodes 110. An operation of forming the photodiodes 110 may include an operation that includes forming an N-type impurity region and an operation of forming a P-type impurity region on the N-type impurity region. A floating diffusion region 128 is formed between the transfer gate 122 and the reset gate 126 in the semiconductor substrate 100. A reset drain region 128 is formed in the semiconductor substrate 100 such that it is disposed adjacent the reset gate 126. Each transistor 120 may include a gate insulating layer 121, a transfer gate 122, a floating diffusion region 124, a reset gate 126, and a reset drain region 128.

Referring to FIG. 5B, a first interlayer dielectric 130 is formed on the semiconductor substrate 100. The first interlayer dielectric 130 may be formed using a CVD method or a spin on glass (SOG) method. A first metal interconnection 135 is formed on the first interlayer dielectric 130. A second interlayer dielectric 140 is formed to cover the first interlayer dielectric 130 and the first metal interconnection 135. A second metal interconnection 145 is formed on the second interlayer dielectric 140. The first and second metal interconnections 135 and 145 may be electrically connected to the transistors 120. A third interlayer dielectric 150 is formed to cover the second metal interconnection 145 and the second interlayer dielectric 140. The first through third interlayer dielectrics 130, 140 and 150 may include a silicon oxide layer with good light transmittance.

Referring to FIG. 5C, a light shielding pattern 160 is formed in the boundary 200 between the light receiving area and an optical black area. An operation of forming the light shielding pattern 160 may include an operation that includes forming a contact hole 155 in the first through third interlayer dielectrics 130, 140 and 150 so as to expose the photodiode 110 in the first optical black area, an operation that includes forming a metal layer that fills the contact hole 155, and an operation that includes planarizing the metal layer. In an embodiment, the contact hole 155 is formed such that a portion of the photodiode 110 in the first optical black area is etched (refer to FIG. 4). An upper light shielding pattern 170 is formed on the third interlayer dielectric 150 so as to be connected to the light shielding pattern 160. The upper light shielding pattern 170 shields oblique light 190 incident to the optical black area. The light shielding pattern 160 and the upper light shielding pattern 170 may be formed at the same time. The light shielding pattern 160 can prevent oblique light 180, which is incident to the light receiving area, from also being incident to the optical black area.

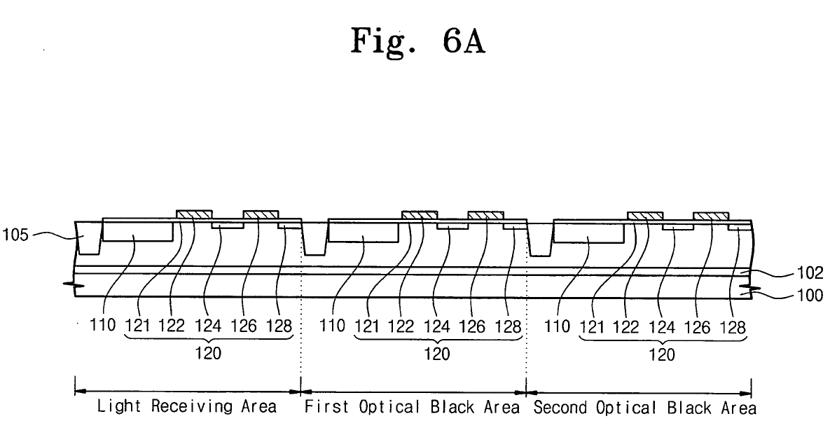

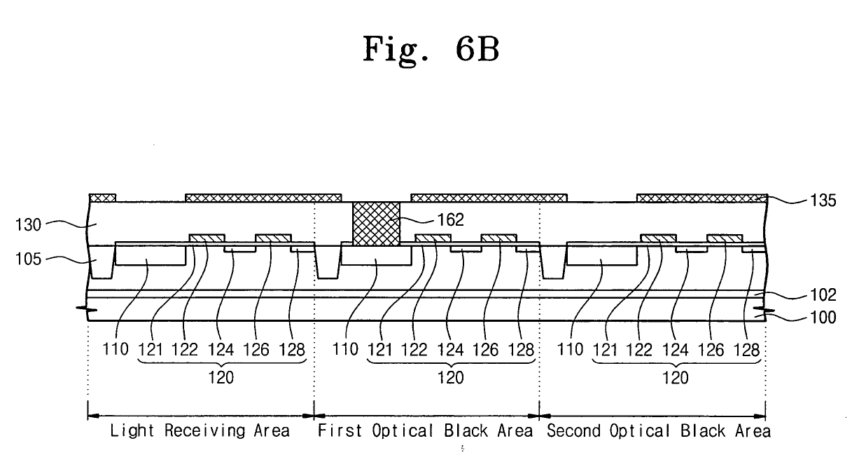

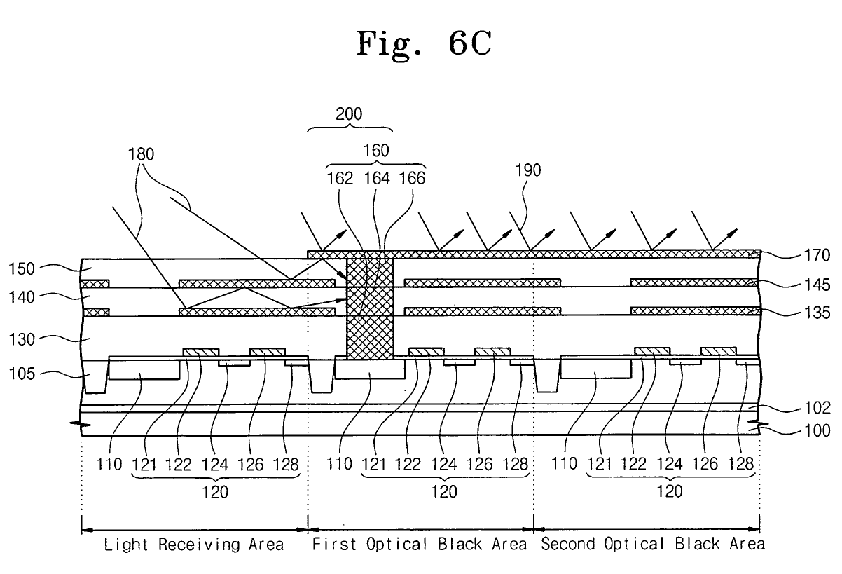

FIGS. 6A through 6C are sectional views illustrating a method of forming an image sensor according to another embodiment of the present invention.

Referring to FIG. 6A, a semiconductor substrate 100 includes a light receiving area, and first and second optical black areas. Similar to FIG. 5A, a P-well 102, a device isolation layer 105, photodiodes 110, and transistors 102 shown in FIG. 6A are formed in the semiconductor substrate 100.

Referring to FIG. 6B, a first interlayer dielectric 130 is formed on the semiconductor substrate 100. The first interlayer dielectric 130 may be formed using a CVD method or a SOG method. A first light shielding pattern 162 is formed on the first interlayer dielectric 130. The first light shielding pattern 162 may be connected to the photodiode 110 in the first optical black area. A first metal interconnection 135 is formed on the first interlayer dielectric 130. The first metal interconnection 135 and the first light shielding pattern 162 may be simultaneously formed using a dual damascene process.

Referring to FIG. 6C, a second interlayer dielectric 140 is formed to cover the first light shielding pattern 162 and the first metal interconnection 135. A second light shielding pattern 164 is formed in the second interlayer dielectric 140 so as to be connected to the first light shielding pattern 162. A second metal interconnection 145 is formed on the second interlayer dielectric 140. The second light shielding pattern 164 and the second metal interconnection 145 may be simultaneously formed using a dual damascene process. A third interlayer dielectric 150 is formed to cover the second light shielding pattern 164 and the second metal interconnection 145. The first through third interlayer dielectrics 130, 140 and 150 may include a silicon oxide layer with good light transmittance. A third light shielding pattern 166 is formed in the third interlayer dielectric 150 so as to be connected to the second light shielding pattern 162. Therefore, a light shielding pattern 160 is formed such that it is configured with the first through third light shielding patterns 162, 164 and 166. An upper light shielding pattern 170 is formed on the third interlayer dielectric 150 so as to be connected to the light shielding pattern 160. The upper light shielding pattern 170 shields oblique light 190 incident to the optical black area. The third light shielding pattern 166 and the upper light shielding pattern 170 may be formed at the same time. The light shielding pattern 160 can prevent oblique light 180, which is incident to the light receiving area, from being incident to the optical black area.

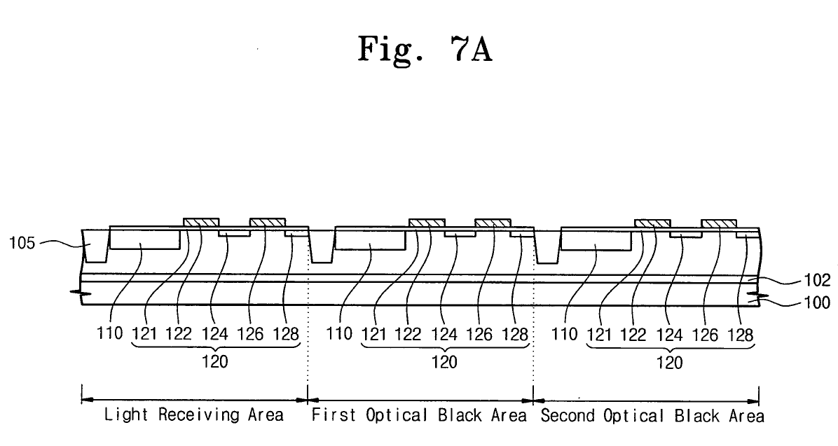

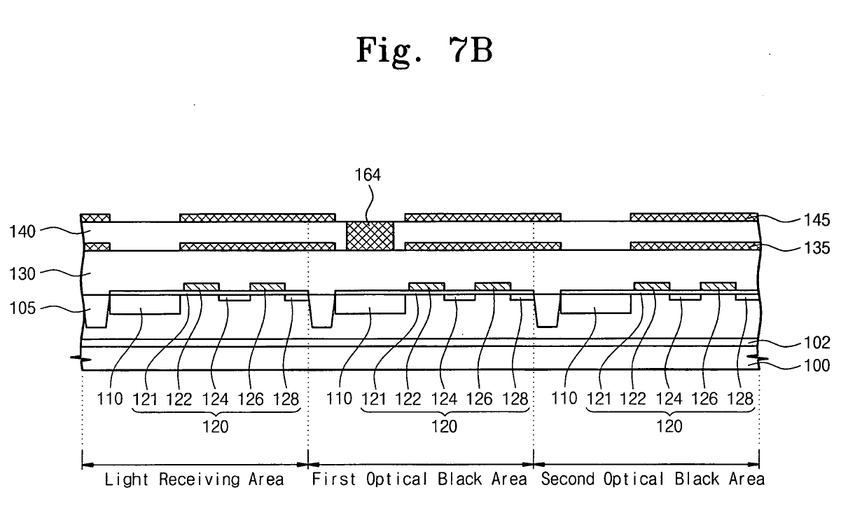

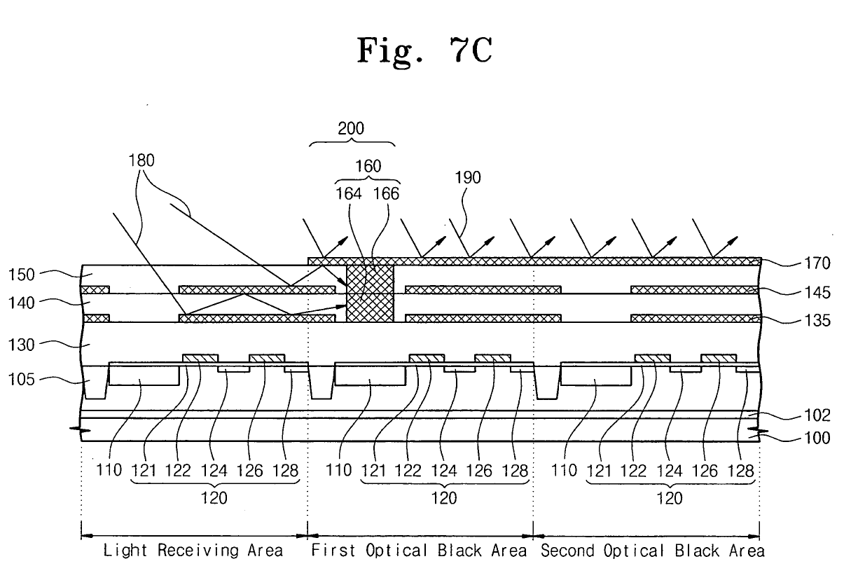

FIGS. 7A through 7C are sectional views illustrating a method of forming an image sensor according to yet another embodiment of the present invention.

Referring to FIG. 7A, a semiconductor substrate 100 includes a light receiving area, and first and second optical black areas. Similar to FIG. 6A, a P-well 102, a device isolation layer 105, photodiodes 110, and transistors 102 shown in FIG. 7A are formed in the semiconductor substrate 100.

Referring to FIG. 7B, a first interlayer dielectric 130 is formed on the semiconductor substrate 100. The first interlayer dielectric 130 may be formed using a CVD method or a SOG method. A first metal interconnection 135 is formed on the first interlayer dielectric 130. A second interlayer dielectric 140 is formed to cover the first interlayer dielectric 130 and the first metal interconnection 135. A second light shielding pattern 164 is formed in the second interlayer dielectric 140. A second metal interconnection 145 is formed on the second interlayer dielectric 140. The second light shielding pattern 164 and the second metal interconnection 145 may be simultaneously formed using a dual damascene process.

Referring to FIG. 7C, a third interlayer dielectric 150 is formed to cover the second light shielding pattern 164 and the second metal interconnection 145. The first through third interlayer dielectrics 130, 140 and 150 may include a silicon oxide layer with good light transmittance. A third light shielding pattern 166 is formed in the third interlayer dielectric 150 so as to be connected to the second light shielding pattern 162. A light shielding pattern 160 is formed such that it is configured with the second and third light shielding patterns 164 and 166. An upper light shielding pattern 170 is formed on the third interlayer dielectric 150 so as to be connected to the light shielding pattern 160. The upper light shielding pattern 170 shields oblique light 190 incident to the optical black area. The third light shielding pattern 166 and the upper light shielding pattern 170 may be formed at the same time. The light shielding pattern 160 can sufficiently prevent oblique light 180, which is incident to the light receiving area, from being incident to the optical black area.

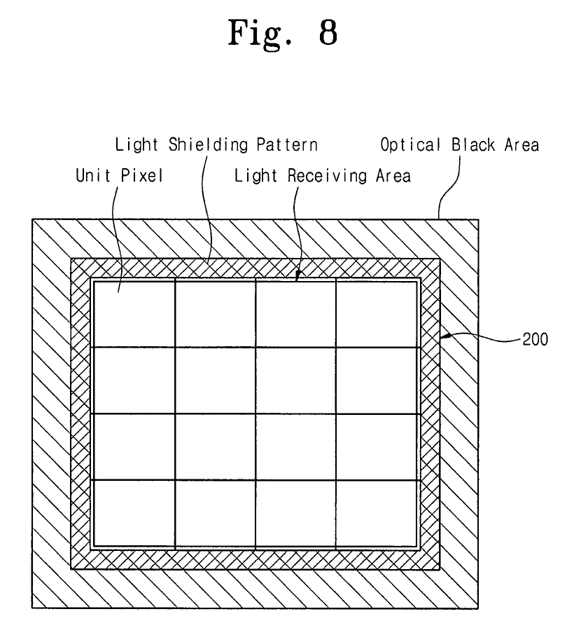

FIGS. 8 through 10 are plan views illustrating a pixel array of an image sensor according to embodiments of the present invention.

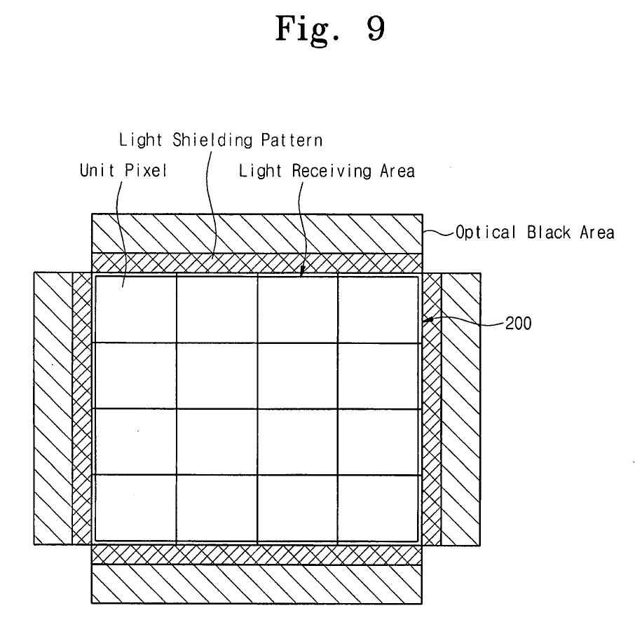

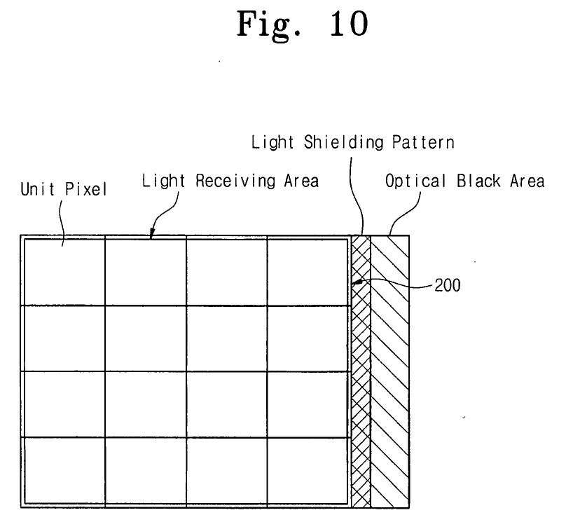

A light shielding pattern is disposed in the boundary 200 between a light receiving area and an optical black area. The light shielding pattern can prevent oblique light, which is incident to the light receiving area, from being incident to the optical black area. Referring to FIG. 8, the light receiving area is surrounded by the optical black area. The light receiving area includes aligned unit pixels. Referring to FIG. 9, an optical black area surrounds a light receiving area. However, as distinguished from FIG. 8, the optical black area shown in FIG. 9 may be disposed at each side of the light receiving area. Referring to FIG. 10, an optical black area is disposed at one side of a light receiving area. In FIGS. 8 through 10, the light shielding pattern may be disposed between an upper light shielding pattern and a photodiode in the optical black area.

According to embodiments of the present invention, a light shielding pattern is provided in the boundary 200 between a light receiving area and an optical black area. The light shielding pattern can prevent oblique light, which is incident to the light receiving area, from being incident to the optical black area. Accordingly, optical cross-talk can be prevented, and, thus, image quality of an image sensor can be improved.

While the foregoing has described what are considered to be the best mode and/or other preferred embodiments, it is understood that various modifications can be made therein and that the invention or inventions may be implemented in various forms and embodiments, and that they may be applied in numerous applications, only some of which have been described herein. It is intended by the following claims to claim that which is literally described and all equivalents thereto, including all modifications and variations that fall within the scope of each claim.

What is claimed is:

1. An image sensor, comprising:
a semiconductor substrate including a light receiving area and an optical black area defined by a boundary between them;
photodiodes in at least one of the light receiving area and the optical black area of the semiconductor substrate;
an interlayer dielectric on the semiconductor substrate;
an upper light shielding pattern on the interlayer dielectric to cover the optical black area; and
a light shielding pattern in the interlayer dielectric proximal to the boundary between the optical black area and the light receiving area.

2. The image sensor of claim 1, wherein the light shielding pattern is interposed between the upper light shielding pattern and a photodiode of the photodiodes in the optical black area.

3. The image sensor of claim 2, wherein the light shielding pattern connects the photodiode in the optical black area to the upper light shielding pattern.

4. The image sensor of claim 3, wherein a bottom surface of the light shielding pattern is lower than a top surface of the semiconductor substrate.

5. The image sensor of claim 1, wherein the light shielding pattern comprises the same material as the upper light shielding pattern.

6. The image sensor of claim 1, further comprising:
at least one transistor adjacent the photodiodes; and
a metal interconnection disposed on the interlayer dielectric to cover the at least one transistor.

7. The image sensor of claim 6, wherein the light shielding pattern comprises the same material as the metal interconnections.

8. The image sensor of claim 1, wherein the optical black area comprises a first optical black area adjacent the light receiving area and a second optical black area adjacent the first optical black area and separated from the light receiving area, wherein the light shielding pattern is in the first optical black area.

9. The image sensor of claim 8, wherein the light receiving area is surrounded by the optical black area.

10. The image sensor of claim 8, wherein the optical black area is disposed at one side of the light receiving area.

11. A method of forming an image sensor, the method comprising:
preparing a semiconductor substrate including a light receiving area and an optical black area defined by a boundary between them;
forming photodiodes in at least one of the light receiving area and the optical black area of the semiconductor substrate;
forming an interlayer dielectric on the semiconductor substrate;
forming a light shielding pattern in the interlayer dielectric proximal to the boundary between the light receiving area and the optical black area; and
forming an upper light shielding pattern on the interlayer dielectric in the optical black area.

12. The method of claim 11, wherein the light shielding pattern is formed between the upper light shielding pattern and the photodiode in the optical black area.

13. The method of claim 11, wherein the forming of the light shielding pattern comprises:
forming a contact hole in the interlayer dielectric such that the photodiode in the optical black area is exposed; and
forming a metal layer to fill the contact hole.

14. The method of claim 11, further comprising:
forming at least one transistor adjacent the photodiodes over the semiconductor substrate; and
forming a metal interconnection on the interlayer dielectric to cover the at least one transistor.

15. The method of claim 14, wherein forming the interlayer dielectric comprises:
forming a first interlayer dielectric;
forming a second interlayer dielectric on the first interlayer dielectric; and
forming a third interlayer dielectric on the second interlayer dielectric, and wherein forming the light shielding pattern comprises:
forming a first light shielding pattern that is connected to the photodiode of the optical black area in the first interlayer dielectric;
forming a second light shielding pattern that is connected to the first light shielding pattern in the second interlayer dielectric; and
forming a third light shielding pattern that is connected to the second light shielding pattern in the third interlayer dielectric.

16. The method of claim 15, wherein forming the metal interconnection comprises:
forming a first metal interconnection on the first interlayer dielectric and forming a second metal interconnection on the second interlayer dielectric to cover the first metal interconnection, wherein
the first light shielding pattern and the first metal interconnection are formed at the same time, wherein
the second light shielding pattern and the second metal interconnection are formed at the same time, and wherein
the third light shielding pattern and the upper light shielding pattern are formed at the same time.

17. The method of claim 14, wherein forming the interlayer dielectric comprises:
forming a first interlayer dielectric;
forming a second interlayer dielectric on the first interlayer dielectric; and
forming a third interlayer dielectric on the second interlayer dielectric, wherein forming the light shielding pattern comprises:
forming a second light shielding pattern in the second interlayer dielectric; and
forming a third light shielding pattern that is connected to the second light shielding pattern in the third interlayer dielectric.

18. The method of claim 17, wherein forming the metal interconnection comprises:
forming a first metal interconnection on the first interlayer dielectric and forming a second metal interconnection on the second interlayer dielectric to cover the first metal interconnection, wherein
the second light shielding pattern and the second metal interconnection are formed at the same time, and wherein
the third light shielding pattern and the upper light shielding pattern are formed at the same time.

19. The method of claim 11, wherein the optical black area comprises a first optical black area adjacent the light receiving area and a second optical black area adjacent the first optical black area and separated from the light receiving area, wherein the light shielding pattern is formed in the first optical black area.

20. The method of claim 19, wherein the light receiving area is surrounded by the optical black area.

21. The method of claim 19, wherein the optical black area is formed at least at one side of the light receiving area.
